(19) United States
(12) Patent Application Publication
(10) Pub. No.: US 2024/0363421 A1
(43) Pub. Date: Oct. 31, 2024

(54) Semiconductor Devices With A Rare Earth Metal Oxide Layer

(71) Applicant: Taiwan Semiconductor Manufacturing Company, Ltd., Hsinchu (TW)

(72) Inventors: Han-Yu LIN, Hsinchu City (TW); Szu-Hua Chen, Hsinchu City (TW); Kuan-Kan Hu, Hsinchu City (TW); Kenichi Sano, Hsinchu City (TW); Po-Cheng Wang, Kaohsiung City (TW); Wei-Yen Woon, Hsinchu (TW); Pinyen Lin, Rochester, NY (US); Che Chi Shih, Hsinchu (TW)

(73) Assignee: Taiwan Semiconductor Manufacturing Company, Ltd., Hsinchu (TW)

(21) Appl. No.: 18/766,104

(22) Filed: Jul. 8, 2024

Related U.S. Application Data
(63) Continuation of application No. 17/533,372, filed on Nov. 23, 2021, now Pat. No. 12,062,576.
(60) Provisional application No. 63/222,863, filed on Jul. 16, 2021.

(51) Int. Cl. H01L 21/8234; H01L 29/06; H01L 29/423; H01L 29/66; H01L 29/786

(52) U.S. Cl. CPC H01L 21/823431; H01L 21/823412; H01L 21/823418; H01L 29/0665; H01L 29/42392; H01L 29/6675; H01L 29/78618; H01L 29/78672; H01L 29/7869; H01L 29/78696

(57) ABSTRACT

The present disclosure describes a semiconductor device with a rare earth metal oxide layer and a method for forming the same. The method includes forming fin structures on a substrate and forming superlattice structures on the fin structures, where each of the superlattice structures includes a first-type nanostructured layer and a second-type nanostructured layer. The method further includes forming an isolation layer between the superlattice structures, implanting a rare earth metal into a top portion of the isolation layer to form a rare earth metal oxide layer, and forming a polysilicon structure over the superlattice structures. The method further includes etching portions of the superlattice structures adjacent to the polysilicon structure to form a source/drain (S/D) opening and forming an S/D region in the S/D opening.

### CROSS-REFERENCE TO RELATED APPLICATION

This application is a continuation of U.S. patent application Ser. No. 17/533,372, filed Nov. 23, 2021, titled “Semiconductor Devices with a Rare Earth Metal Oxide Layer,” which claims the benefit of U.S. Provisional Patent Application No. 63/222,863, filed Jul. 16, 2021, titled “Implanted Hybrid Fin for SSD Etch,” each of which is incorporated by reference herein in its entirety.

### BACKGROUND

With advances in semiconductor technology, there have been increasing demands for higher storage capacity, faster processing systems, higher performance, and lower costs. To meet these demands, the semiconductor industry continues to scale down the dimensions of semiconductor devices with three-dimensional transistors, such as gate-all-around (GAA) field effect transistors (FETs) and fin field effect transistors (finFETs).

### BRIEF DESCRIPTION OF THE DRAWINGS

Aspects of the present disclosure are best understood from the following detailed description when read with the accompanying figures.

FIG. 1A illustrates an isometric view of a semiconductor device with a rare earth metal oxide layer, in accordance with some embodiments.

FIGS. 1B-1D illustrate cross-sectional views of a semiconductor device with a rare earth metal oxide layer, in accordance with some embodiments.

FIGS. 2A and 2B are flow diagrams of a method for fabricating a semiconductor device with a rare earth metal oxide layer, in accordance with some embodiments.

FIGS. 3-20 illustrate isometric views of a semiconductor device with a rare earth metal oxide layer at various stages of its fabrication process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the embodiments and/or configurations discussed herein.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., +1%, +2%, +3%, +4%, +5% of the value). These values are merely examples and are not intended to be limiting. The terms “about” and “substantially” can refer to a percentage of the values as interpreted by those skilled in relevant art(s) in light of the teachings herein.

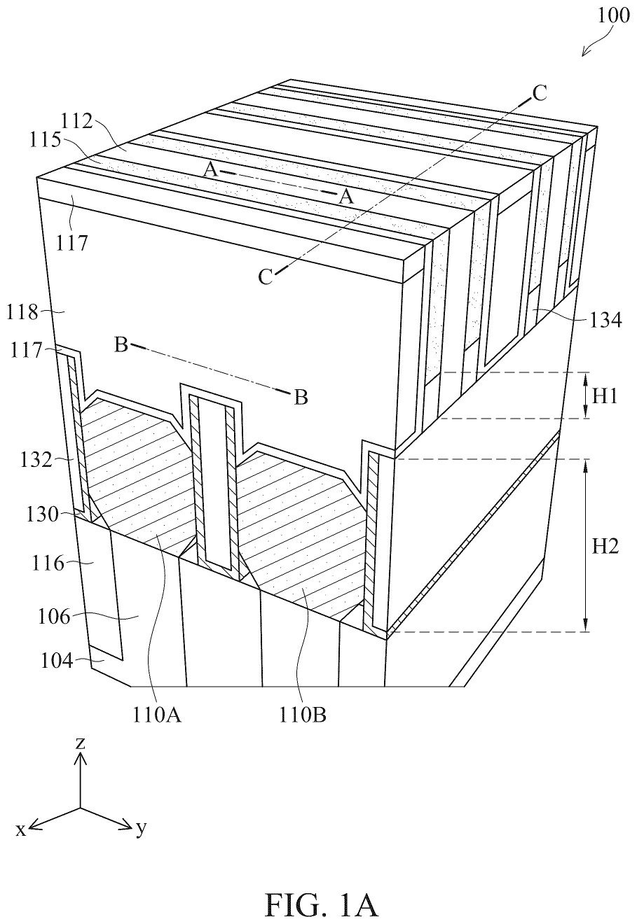

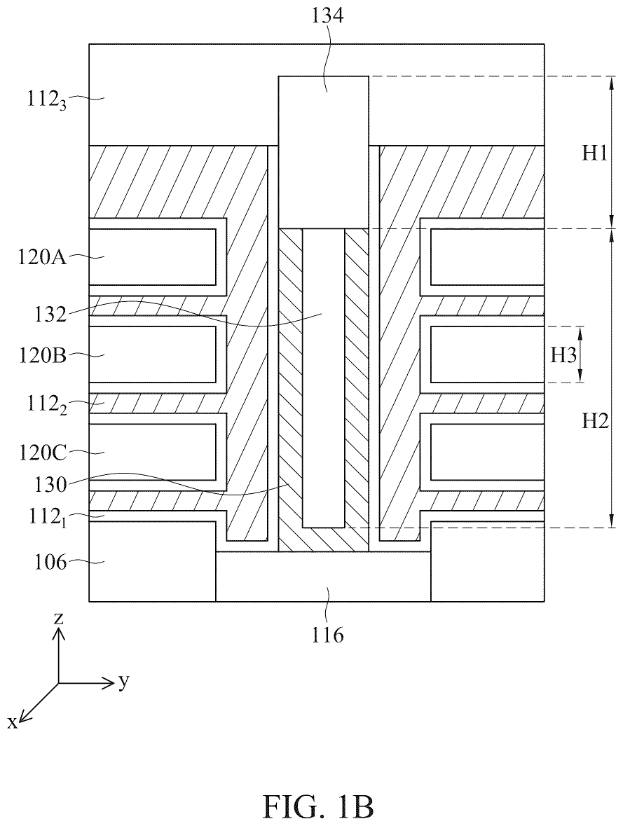

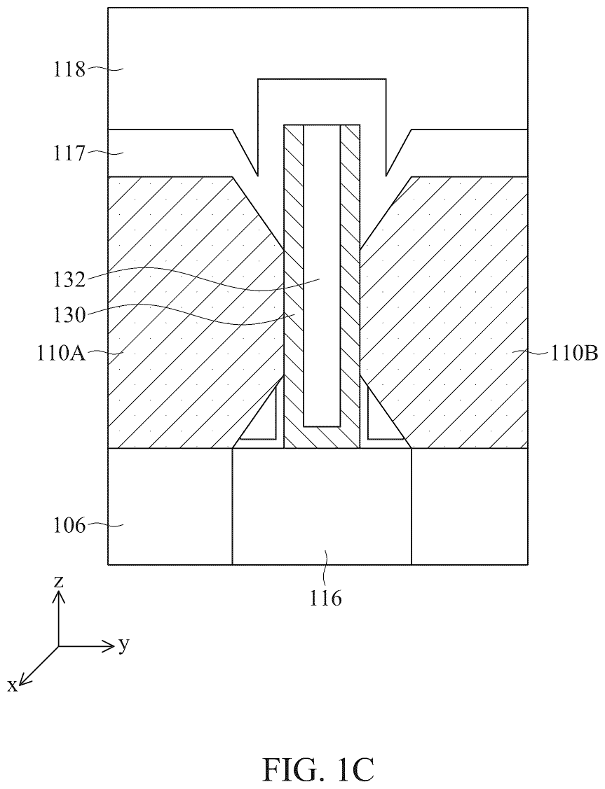

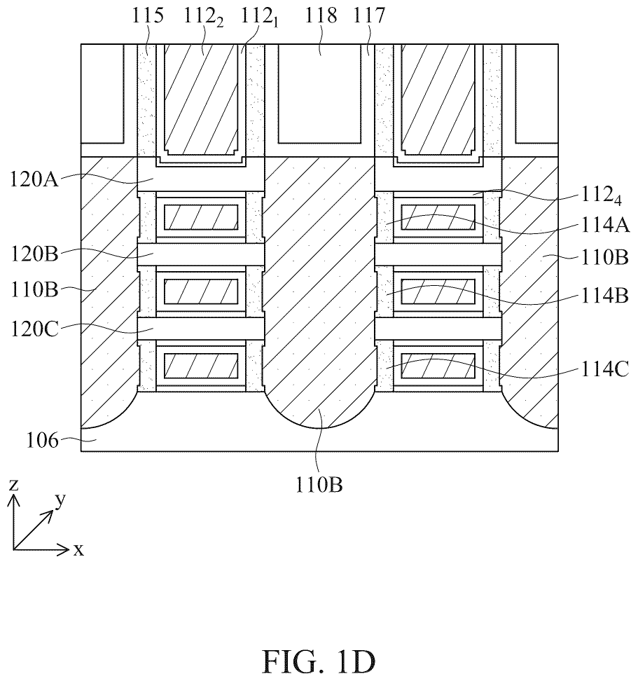

The discussion of elements in FIGS. 1A-1D, 3-8A, 8D-8E, 9-16, 17A-17B, and 18-20 with the same annotations applies to each other, unless mentioned otherwise.

As the semiconductor industry continues to scale down the dimensions of semiconductor devices, circuit complexity has increased at all device levels. Gate-all-around (GAA) field effect transistors (FETs) and fin field effect transistors (finFETs) increase device density and improve device performance. GAA FETs and finFETs include a pair of source/drain (S/D) regions formed on opposite sides of a channel region and a gate structure formed on the channel region. In some embodiments, there can be multiple S/D regions on the same side of the channel region, with an isolation layer between each two of the multiple S/D regions. When forming the S/D regions, portions of fin structures adjacent to the gate structure can be removed by etching. The S/D regions can be epitaxially grown in the removed portions of the fin structures. During the etching of the portions of the fin structures, a top portion of the isolation layer can also be removed. If too much of the top portion of the isolation layer is removed, the epitaxially-grown S/D regions can merge together over the isolation layer. The merged S/D regions can increase the complexity of the circuit design and reduce device performance and reliability.

The present disclosure provides example FET devices (e.g., GAA FETs, finFETs, and planar FETs) with a rare earth metal oxide layer in a semiconductor device and/or in an integrated circuit (IC) and an example method for fabricating the same. The rare earth metal oxide layer can be formed on the top portion of the isolation layer to protect the top portion of the isolation layer from etching. There can be two methods for forming the rare earth metal oxide layer on the top portion of the isolation layer. The first method can be rare earth metal implantation on the top portion of both the isolation layer and the fin structures. There can be a post-implantation anneal. The rare earth metal can react with the isolation layer to form the rare earth metal oxide layer. The top portion of the implanted fin structures can be removed, leaving the isolation layer with the rare earth metal oxide layer on the top portion of the isolation layer. The second method can be rare earth metal oxide deposition. The top portion of the isolation layer can be removed to form an isolation layer opening. The rare earth metal oxide layer can be deposited in the isolation layer opening and on the fin structures. The deposition can be atomic layer deposition (ALD). There can be a post-deposition anneal. The excess rare earth metal oxide layer on the isolation layer and on the fin structures can be polished using chemical-mechanical planarization (CMP). When forming the S/D regions, portions of the fin structures adjacent to the gate structure can be removed by etching. The S/D regions can be epitaxially grown in the removed portions of the fin structures. During the etching of the portions of the fin structures, the rare earth metal oxide layer can protect the top portion of the isolation layer from being removed. If too much of the top portion of the isolation layer is removed, the epitaxially-grown S/D regions can merge together over the isolation layer. The merged S/D regions can increase the complexity of the circuit design and reduce device performance and reliability. Protected isolation layer can prevent the S/D regions from merging together over the isolation layer. Therefore, the rare earth metal oxide layer can reduce circuit complexity and improve device performance and reliability.

According to some embodiments, FIG. 1A illustrates an isometric view of a FET 100. Though a GAA FET 100 is shown here to represent FET 100, in some embodiments, FET 100 can also represent a finFET 100. In some embodiments, FET 100 can represent n-type FET 100 (NFET 100) and p-type FET 100 (PFET 100) and the discussion of FET 100 applies to both NFET 100 and PFET 100, unless mentioned otherwise. FIG. 1B illustrates a cross-sectional view of FET 100 along line A-A in FIG. 1A showing relative positions between isolation layer 132, liner 130, rare earth metal oxide layer 134, gate structure elements 112₁-112₃, nanostructured channel regions 120A-120C, fin structures 106, and shallow trench isolation (STI) region 116. FIG. 1C illustrates a cross-sectional view of FET 100 along line B-B in FIG. 1A showing relative positions between S/D regions 110A and 110B, isolation layer 132, liner 130, etch stop layer (ESL) 117, interlayer dielectric (ILD) layer 118, fin structures 106, and STI region 116. FIG. 1D illustrates a cross-sectional view of FET 100 along line C-C in FIG. 1A showing relative positions between ESLs 117, ILD layers 118, gate structure elements 112₁, 112₂, and 112₄, nanostructured channel regions 120A-120C, spacers 115, inner spacers 114A-114C, fin structure 106, and S/D regions 110B.

Referring to FIGS. 1A, 1B, and 1D, FET 100 can include gate structures 112 disposed on fin structures 106. Referring to FIGS. 1B and 1D, FET 100 can include gate regions disposed between nanostructured channel regions 120A-120C and on fin structures 106. Referring to FIGS. 1A, 1C, and 1D, FET 100 can include S/D regions 110A and 110B disposed on portions of fin structures 106 that are adjacent to gate structures 112. Referring to FIGS. 1A and 1D, FET 100 can further include gate spacers 115. Referring to FIG. 1D, FET 100 can further include inner spacers 114A-114C. Referring to FIGS. 1A-1C, FET 100 can further include STI regions 116. Referring to FIGS. 1A-1C, FET 100 can further include isolation layers 132 and liners 130. Referring to FIGS. 1A, 1C, and 1D, FET 100 can further include ESLs 117 and ILD layers 118. ILD layers 118 can be disposed on ESLs 117. In some embodiments, gate spacers 115, inner spacers 114A-114C, STI regions 116, isolation layers 132, liners 130, ESLs 117, and ILD layers 118 can include an insulating material, such as silicon oxide (SiOₓ), silicon nitride (SiN), silicon carbon nitride (SiCN), silicon oxycarbon nitride (SiOCN), and silicon germanium oxide (SiGeOₓ).

Referring to FIG. 1A, FET 100 can be formed on a substrate 104. There can be other FETs and/or structures (e.g., isolation structures) formed on substrate 104. Substrate 104 can be a semiconductor material, such as silicon (Si), germanium (Ge), silicon germanium (SiGe), a silicon-on-insulator (SOI) structure, and a combination thereof. Further, substrate 104 can be doped with p-type dopants, such as boron (B), indium (In), aluminum (Al), and gallium (Ga), or n-type dopants, such as phosphorous (P) and arsenic (As). In some embodiments, fin structures 106 can include a material similar to substrate 104 and extend along an X-axis.

Referring to FIGS. 1B and 1D, in some embodiments, FET 100 can include nanostructured channel regions 120A-120C. Nanostructured channel regions 120A-120C can include a semiconductor material, similar to or different from substrate 104. Nanostructured channel regions 120A-120C can include a semiconductor material, similar to fin structures 106 and S/D regions 110A and 110B. In some embodiments, nanostructured channel regions 120A-120C can include Si, silicon arsenide (SiAs), silicon phosphide (SiP), silicon carbide (SiC), silicon carbon phosphide (SiCP), SiGe, silicon germanium boron (SiGeB), germanium boron (GeB), silicon germanium stannum boron (SiGeSnB), a III-V semiconductor compound, and other suitable semiconductor materials. Nanostructured channel regions 120A-120C can be nanosheets and nanowires. Nanostructured channel regions 120A-120C can have cross-sections of other geometric shapes, such as circular, elliptical, triangular, and polygonal shapes.

Referring to FIGS. 1A-1B and 1D, in some embodiments, gate structures 112 can be multi-layered structures. For FET 100, the gate regions disposed between the nanostructured channel regions can also be multi-layered structures. Each of gate structures 112 and the gate regions can include an interfacial oxide (IO) layer 112₄, a high-k (HK) gate dielectric layer 112₁ disposed on IO layer 112₄, and a conductive layer disposed on HK gate dielectric layer 112₁. IO layers 112₄ can include SiOₓ, SiGeOₓ, and germanium oxide (GeOₓ). HK gate dielectric layers 112₁ can include a HK dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). The conductive layers can be multi-layered structures. Each of the conductive layers can include a work function metal (WFM) layer 112₂ disposed on HK gate dielectric layer 112₁, and a gate metal fill layer 112₃ disposed on WFM layer 112₂. In some embodiments, WFM layers 112₂ can include titanium aluminum (TiAl), titanium aluminum carbide (TiAlC), tantalum aluminum (TaAl), tantalum aluminum carbide (TaAlC), Al-doped titanium (Ti), Al-doped titanium nitride (TiN), Al-doped tantalum (Ta), Al-doped tantalum nitride (TaN), other suitable Al-based materials, and a combination thereof. In some embodiments, WFM layers 112₂ can include substantially Al-free (e.g., with no Al) Ti-based and Ta-based nitrides and alloys, such as TiN, titanium silicon nitride (TiSiN), titanium gold (Ti—Au) alloy, titanium copper (Ti—Cu) alloy, TaN, tantalum silicon nitride (TaSiN), tantalum gold (Ta—Au) alloy, tantalum copper (Ta—Cu), and a combination thereof. Gate metal fill layers 112₃ can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

Referring to FIGS. 1A, 1C, and 1D, for NFET 100, each of S/D regions 110A and 110B can include an epitaxially grown semiconductor material, such as Si and SiGe, and n-type dopants, such as P and other suitable n-type dopants. For PFET 100, each of S/D regions 110A and 110B can include an epitaxially grown semiconductor material, such as Si and SiGe, and p-type dopants, such as B and other suitable p-type dopants. A dopant concentration can be in a range from about 1×10²⁰ atoms/cm³ to about 3×10²² atoms/cm³ in each of S/D regions 110A and 110B. In some embodiments, S/D regions 110A and 110B can have a depth of about 50 nm to about 70 nm.

Referring to FIGS. 1A and 1B, FET 100 can further include rare earth metal oxide layers 134. If rare earth metal oxide layers 134 are formed by implanting rare earth metal atoms into isolation layers 132 and liners 130, rare earth metal oxide layers 134 can include a composition of MₓSi_{y}O_{z}, where (i) element M can be a rare earth metal, such as hafnium (Hf), lanthanum (La), indium (In), rhodium (Rh), palladium (Pd), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and combinations thereof; (ii) x can be a value between about 0 and about 2, (iii) y can be a value between about 0 and about 1, and (iv) z can be a value between about 1 and about 4. In some embodiments, rare earth metal oxide layers 134 can include carbon (C) and nitrogen (N). The concentration of the rare earth metal atoms in rare earth metal oxide layers 134 can vary with respect to depth. In some embodiments, the concentration can decrease from the top surface of rare earth metal oxide layers 134 to the bottom surface of rare earth metal oxide layers 134. In some embodiments, the concentration can increase first and then decrease from the top surface of rare earth metal oxide layers 134 to the bottom surface of rare earth metal oxide layers 134. The concentration of the rare earth metal atoms in rare earth metal oxide layers 134 can range from about 1×10²⁰ atoms/cm³ to about 3×10²² atoms/cm³. If the concentration is smaller than about 1×10²⁰ atoms/cm³, rare earth metal oxide layers 134 cannot protect isolation layers 132 from etching during S/D region formation. If the concentration is greater than about 3×10²² atoms/cm³, the cost to form rare earth metal oxide layers 134 can be too high.

If rare earth metal oxide layers 134 are formed by implanting rare earth metal atoms into isolation layers 132 and liners 130, a thickness H1 of rare earth metal oxide layers 134 can be between about 1 nm and about 10 nm, between about 0.8 nm and about 12 nm, and between about 0.5 nm and about 15 nm. If H1 is smaller than about 0.5 nm, rare earth metal oxide layers 134 cannot protect isolation layers 132 from etching during S/D region formation. If H1 is greater than about 15 nm, the cost to form rare earth metal oxide layers 134 can be too high. A thickness H2 of isolation layers 132 can be between about 50 nm and about 100 nm. A ratio between H1 and H2 can be between about 0.02 and about 0.2, between about 0.015 and about 0.25, and between about 0.01 and about 0.3. If H1/H2 is smaller than about 0.01, rare earth metal oxide layers 134 cannot protect isolation layers 132 from etching during S/D region formation. If H1/H2 is greater than about 0.3, the cost to form rare earth metal oxide layers 134 can be too high. Referring to FIG. 1B, a thickness H3 of nanostructured channel regions 120A-120C can be between about 1 nm and about 25 nm. A ratio between H1 and H3 can be between about 0.2 and about 2, between about 0.15 and about 2.5, and between about 0.1 and about 3. If H1/H3 is smaller than about 0.1, rare earth metal oxide layers 134 cannot protect isolation layers 132 from etching during S/D region formation. If H1/H3 is greater than about 3, the cost to form rare earth metal oxide layers 134 can be too high.

Referring to FIGS. 1A and 1B, if rare earth metal oxide layers 134 are formed by removing the top portions of isolation layers 132 to form isolation layer openings and filling the isolation layer openings by an ALD process, rare earth metal oxide layers 134 can include a composition of MₓO_{y}, where (i) element M can be a rare earth metal, such as Hf, La, In, Rh, Pd, In, Ce, Pr, Nd, Pm, Sm, Eu, Gd, Tb, Dy, Ho, Er, Tm, Yb, Lu, and combinations thereof, (ii) x can be a value between about 0 and about 2, and (iii) y can be a value between about 0 and about 3. The concentration of the rare earth metal atoms in rare earth metal oxide layers 134 can be substantially uniform. The concentration of the rare earth metal atoms in rare earth metal oxide layers 134 can range from about 1×10²⁰ atoms/cm³ to about 3×10²² atoms/cm³. If the concentration is smaller than about 1×10²⁰ atoms/cm³, rare earth metal oxide layers 134 cannot protect isolation layers 132 from etching during S/D region formation. If the concentration is greater than about 3×10²² atoms/cm³, the cost to form rare earth metal oxide layers 134 can be too high.

If rare earth metal oxide layers 134 are formed by removing the top portions of isolation layers 132 to form isolation layer openings and filling the isolation layer openings by an ALD process, a thickness H1 of rare earth metal oxide layers 134 can be between about 3 nm and about 10 nm, between about 2 nm and about 15 nm, and between about 1 nm and about 20 nm. If H1 is smaller than about 1 nm, rare earth metal oxide layers 134 cannot protect isolation layers 132 from etching during S/D region formation. If H1 is greater than about 20 nm, the cost to form rare earth metal oxide layers 134 can be too high. A thickness H2 of isolation layers 132 can be between about 50 nm and about 100 nm. A ratio between H1 and H2 can be between about 0.06 and about 0.2, between about 0.05 and about 0.25, and between about 0.04 and about 0.3. If H1/H2 is smaller than about 0.04, rare earth metal oxide layers 134 cannot protect isolation layers 132 from etching during S/D region formation. If H1/H2 is greater than about 0.3, the cost to form rare earth metal oxide layers 134 can be too high. Referring to FIG. 1B, a thickness H3 of nanostructured channel regions 120A-120C can be between about 1 nm and about 25 nm. A ratio between H1 and H3 can be between about 0.6 and about 2, between about 0.5 and about 2.5, and between about 0.4 and about 3. If H1/H3 is smaller than about 0.4, rare earth metal oxide layers 134 cannot protect isolation layers 132 from etching during S/D region formation. If H1/H3 is greater than about 3, the cost to form rare earth metal oxide layers 134 can be too high.

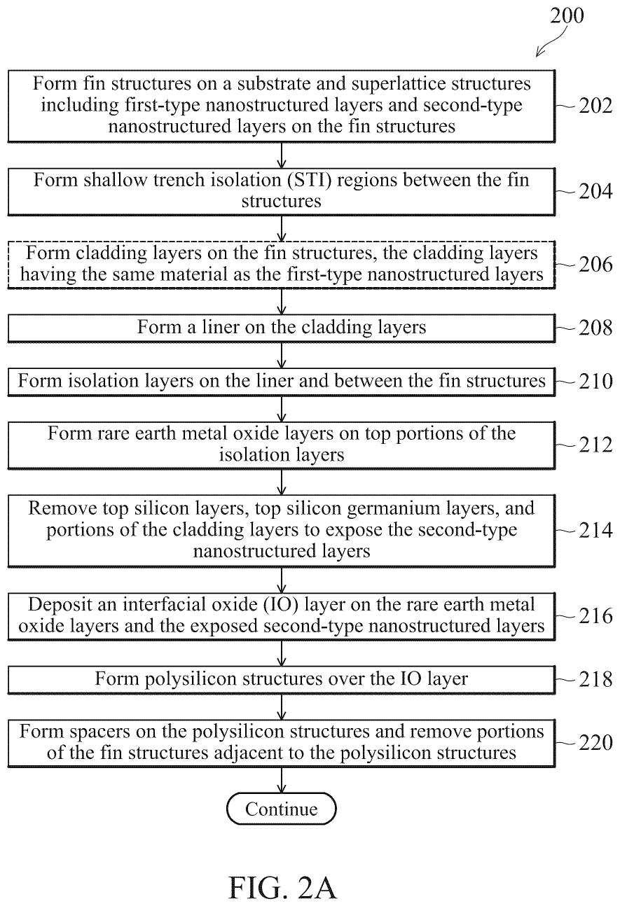

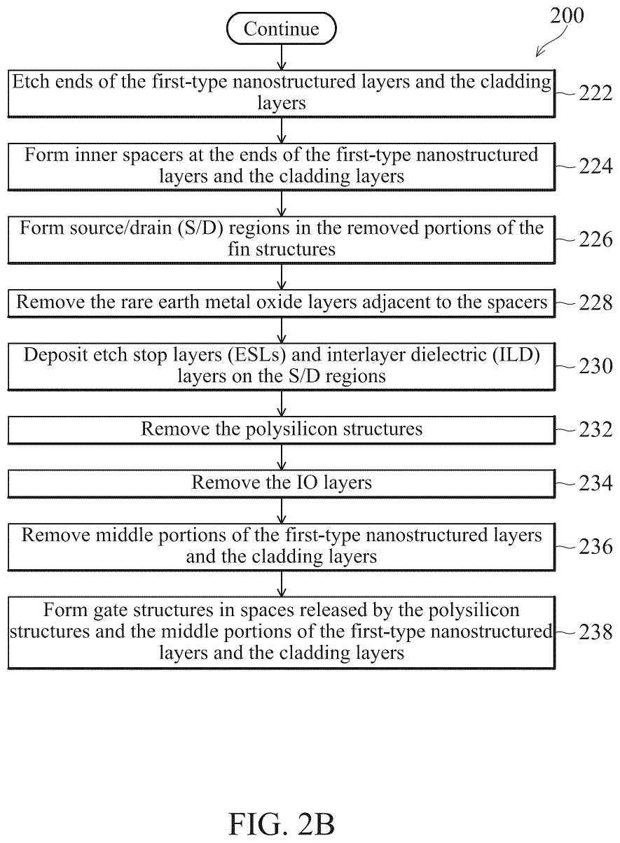

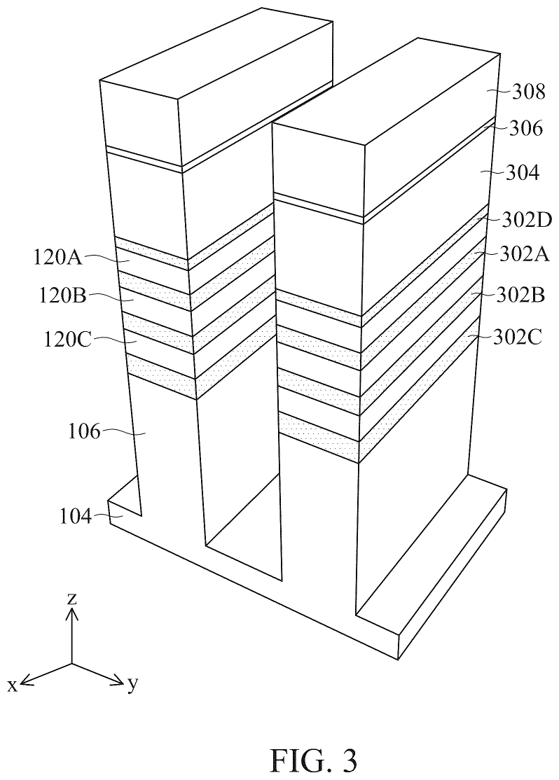

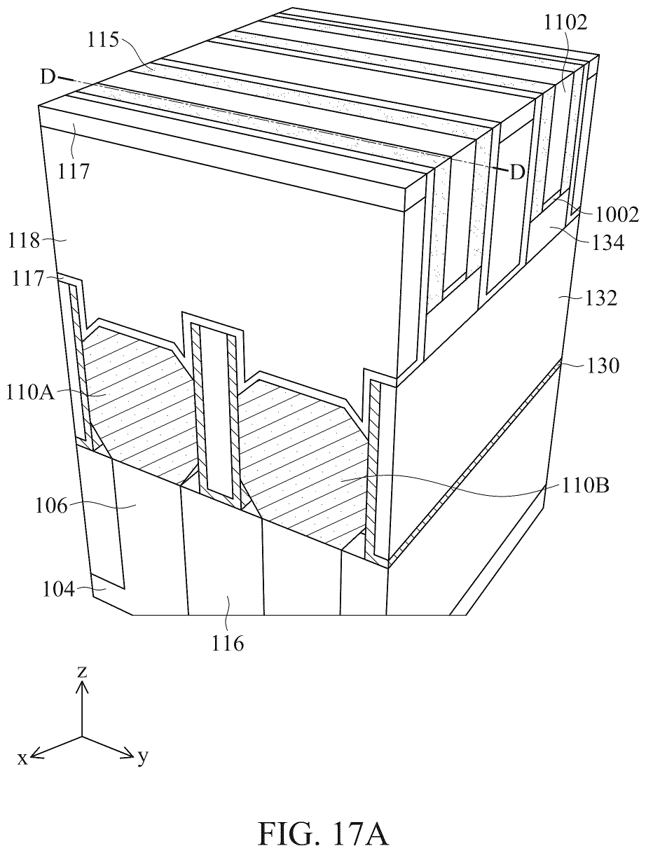

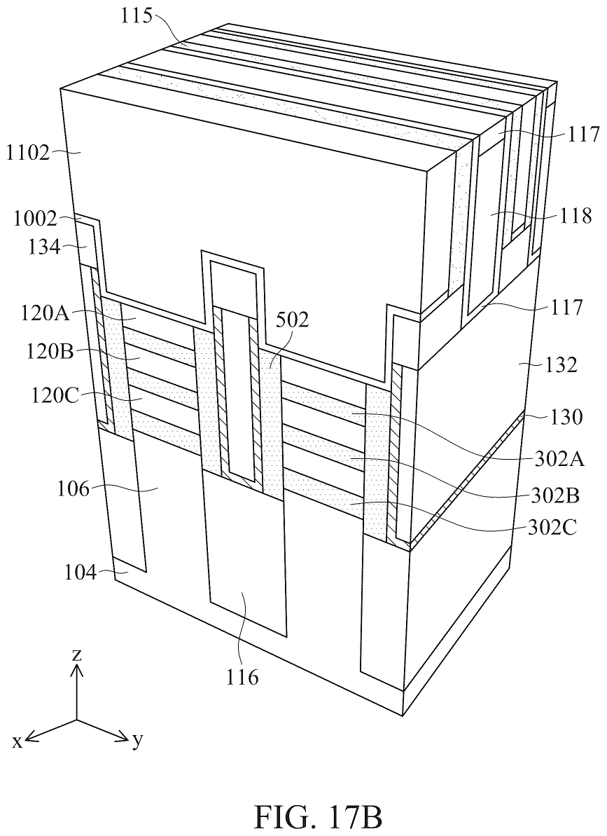

According to some embodiments, FIGS. 2A and 2B are flow diagrams describing a method 200 for fabricating FET 100, as shown in FIGS. 1A-1D. For illustrative purposes, the operations illustrated in FIGS. 2A and 2B will be described with reference to the example fabrication process for fabricating FET 100 as illustrated in FIGS. 3-7, 8A-8E, 9-16, 17A-17B, and 18-20. FIGS. 3-8A and 8D-17A are isometric views of FET 100 at various stages of fabrication, according to some embodiments. FIGS. 17B-20 are isometric views of FET 100 at various stages of fabrication viewed from line D-D in FIG. 17A for case of description of the structures hidden in FIG. 17A, according to some embodiments. Additional fabrication operations can be performed between the various operations of method 200 and are omitted for simplicity. These additional fabrication operations are within the spirit and the scope of this disclosure. Moreover, not all operations may be required to perform the disclosure provided herein. Additionally, some of the operations can be performed simultaneously or in a different order than the ones shown in FIGS. 2A and 2B. It should be noted that method 200 may not produce a complete FET 100. Accordingly, it is understood that additional processes can be provided before, during, and after method 200, and that some other processes may only be briefly described herein. Elements in FIGS. 3-8A, 8D-8E, 9-16, 17A-17B, and 18-20 with the same annotations as elements in FIGS. 1A-1D are described above. Even though method 200 is described with respect to FET 100, method 200 can be performed to fabricate finFET 100.

Referring to FIG. 2A, in operation 202, fin structures are formed on a substrate. For example, as shown in FIG. 3, fin structures 106 are formed on substrate 104. A superlattice structure including first-type nanostructured layers 302A-302C and second-type nanostructured layers 120A-120C can be formed on each of fin structures 106. First-type nanostructured layers 302A-302C can be single crystal SiGe epitaxially grown on fin structures 106. Second-type nanostructured layers 120A-120C can be single crystal Si epitaxially grown on fin structures 106 and interposed between first-type nanostructured layers 302A-302C. Second-type nanostructured layers 120A-120C can function as the nanostructured channel regions in FET 100. A top SiGe layer 302D, a top Si layer 304, a SiOₓ capping layer 306, and a SiN capping layer 308 can be formed on the superlattice structure to act as masking layers and/or ESLs, described below. Fin structures 106 can be patterned by any suitable method.

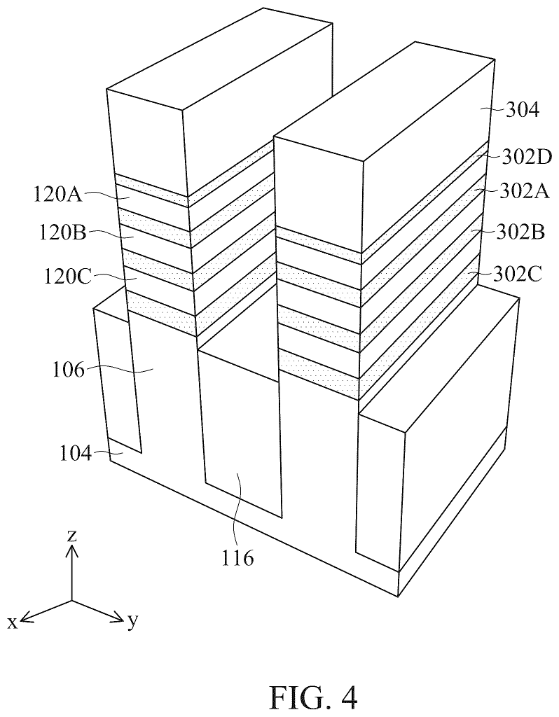

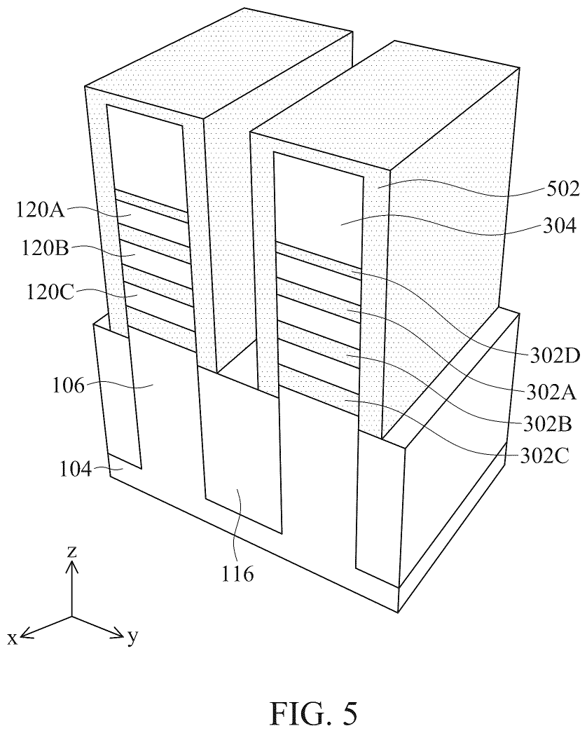

Referring to FIG. 2A, in operation 204, STI regions are formed between the fin structures. For example, as shown in FIG. 4, STI regions 116 are formed between fin structures 106. A STI layer can be blanket deposited using chemical vapor deposition (CVD), physical vapor deposition (PVD), and plasma-enhanced chemical vapor deposition (PECVD). In some embodiments, a post-deposition anneal process can be performed. In some embodiments, a chemical mechanical polishing/planarization (CMP) process can follow the deposition of the STI layer, such that the STI layer is substantially coplanar with SiN capping layer 308. Portions of the STI layer can be removed and recessed by dry etching (e.g., reactive ion etching process) and wet etching to form STI regions 116. SiN capping layer 308 and SiOₓ capping layer 306 can function as ESLs and can be removed in the STI recessing process.

Referring to FIG. 2A, in operation 206, cladding layers are formed on the fin structures. For example, as shown in FIG. 5, cladding layers 502 are formed on fin structures 106. Cladding layers 502 can have the same material as first-type nanostructured layers 302A-302C, such as SiGe. Cladding layers 502 can be amorphous. Cladding layers 502 can be deposited using a CVD process with germane (GeH₄) and disilane (Si₂H₆) as precursors. A dry etch can be performed to remove cladding layers 502 on STI regions 116.

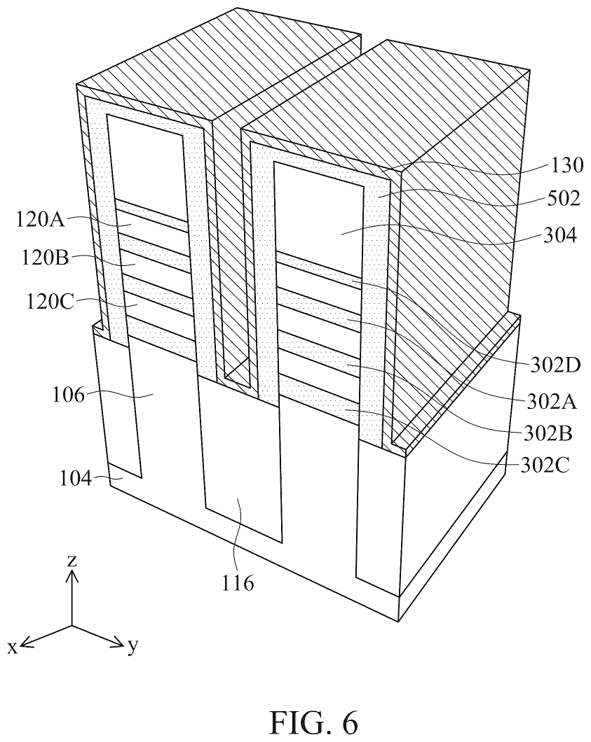

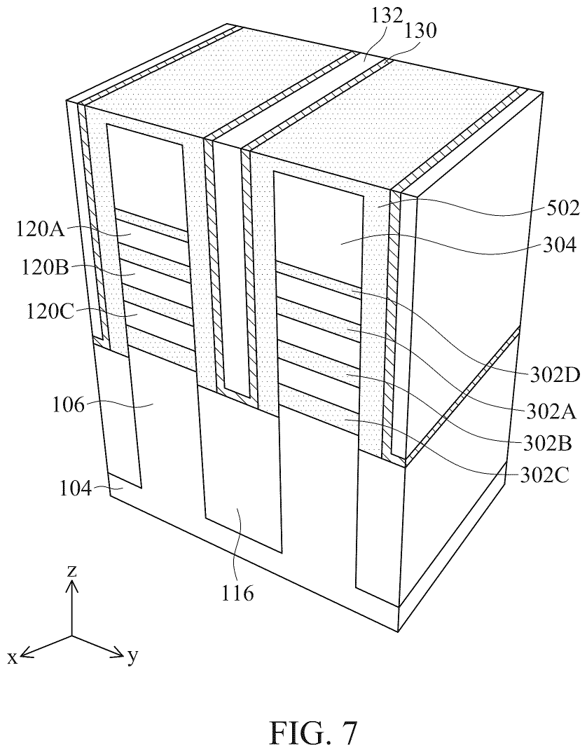

Referring to FIG. 2A, in operation 208, a liner is formed on the cladding layers. For example, as shown in FIG. 6, liner 130 is formed on cladding layers 502. Liner 130 can be a low-k dielectric material, such as a dielectric material with a dielectric constant lower than 3.9. Liner 130 can be deposited using CVD, PVD, and PECVD.

Referring to FIG. 2A, in operation 210, isolation layers are formed on the liner and between the fin structures. For example, as shown in FIG. 7, isolation layers 132 are formed on liner 130 and between fin structures 106. Isolation layers 132 can be an insulating material and can be deposited using CVD, PVD, and PECVD. In some embodiments, a post-deposition anneal process can be performed. In some embodiments, a CMP process can follow the deposition of isolation layers 132, such that isolation layers 132 and liners 130 are substantially coplanar with cladding layers 502.

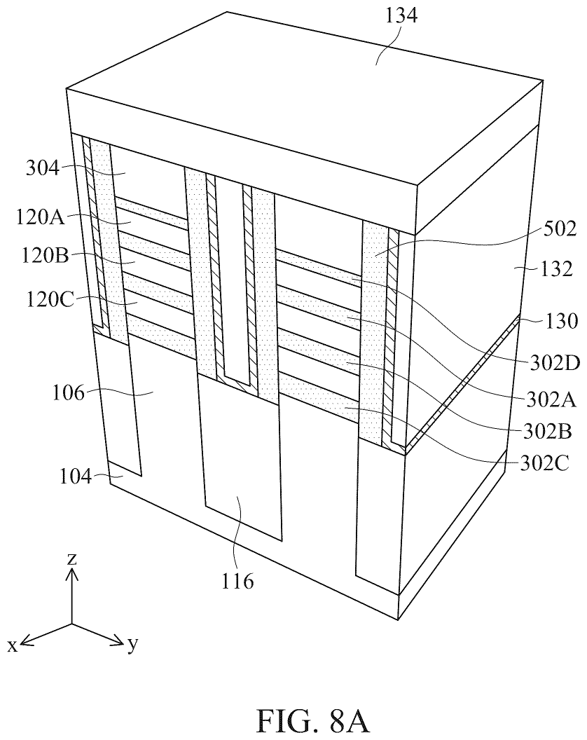

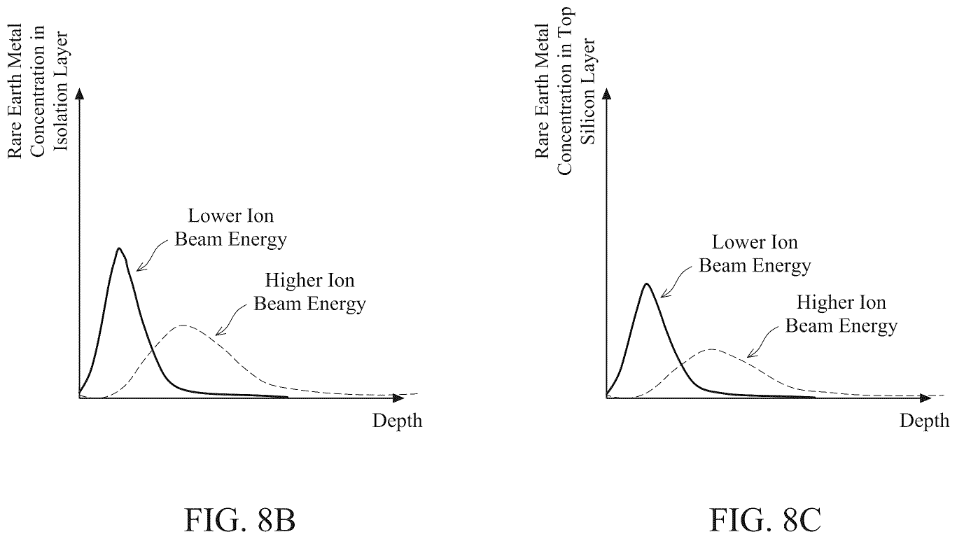

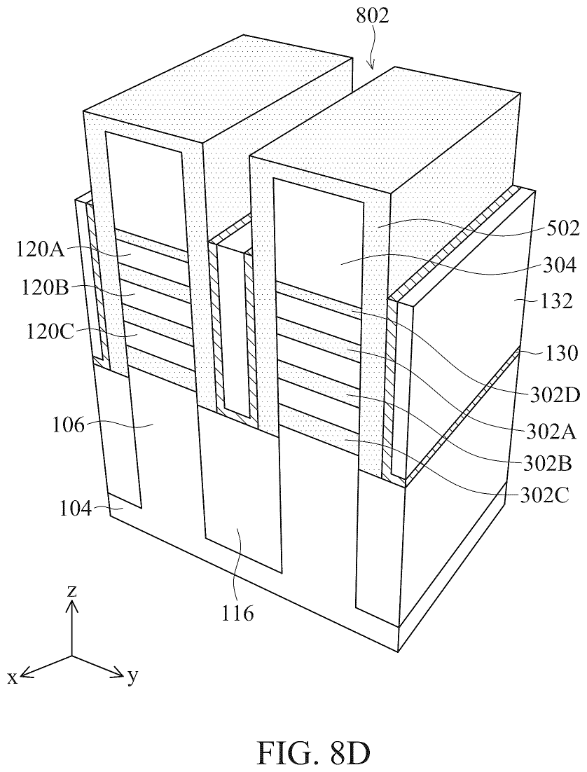

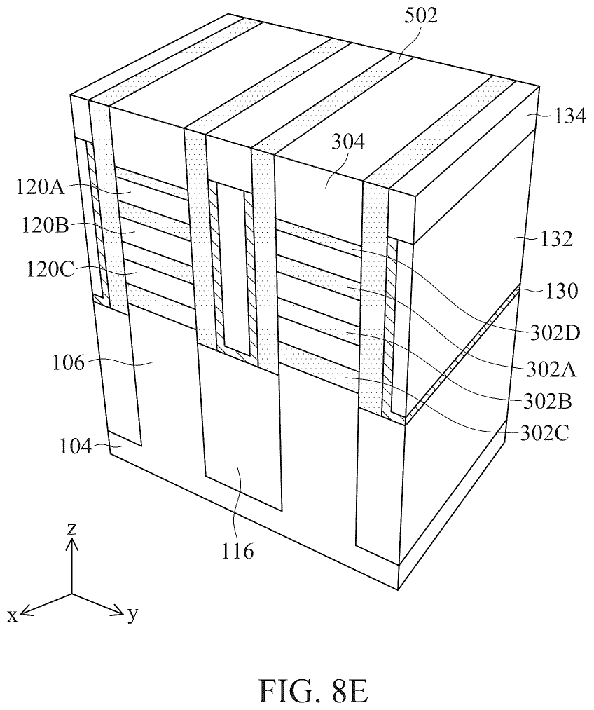

Referring to FIG. 2A, in operation 212, rare earth metal oxide layers are formed on the top portions of the isolation layers. In some embodiments, the rare earth metal oxide layers can be formed by rare earth metal implantation into the isolation layers. For example, rare earth metal implantation can be performed on top portions of isolation layers 132, liners 130, cladding layers 502, and top Si layers 304 of FIG. 7 to form the implanted rare earth metal oxide layer 134 of FIG. 8A.

In some embodiments, the rare earth metal oxide layers can be formed by removing the top portions of isolation layers 132 to form isolation layer openings and filling the isolation layer openings by an ALD process. For example, as shown in FIG. 8D, the top portions of isolation layers 132 and liners 130 are removed to form isolation layer openings 802, and as shown in FIG. 8E, rare earth metal oxide layers 134 are formed in isolation layer openings 802.

Referring to FIG. 8A, rare earth metal implantation is performed on isolation layers 132, liners 130, cladding layers 502, and top Si layers 304. Implantation dopant species can be a rare earth metal, such as Hf, La, In, Rh, Pd, In, Ce, Pr, Nd, Pm, Sm, Eu, Gd, Tb, Dy, Ho, Er, Tm, Yb, Lu, and combinations thereof. The ion beam energy can be between about 1 keV and about 10 keV, between about 0.8 keV and about 12 keV, and between about 0.5 keV and about 15 keV. If the ion beam energy is smaller than about 0.5 keV, the depth of rare earth metal implantation can be too small and rare earth metal oxide layers 134 cannot protect isolation layers 132 from etching during S/D region formation. If the ion beam energy is greater than about 15 keV, the rare earth metal implantation can introduce too many defects and damages to isolation layers 132. The dose of the rare earth metal atoms can be between about 1×10¹⁵ ions/cm² and about 1×10¹⁶ ions/cm², between about 0.8×10¹⁵ ions/cm² and about 1.2×10¹⁶ ions/cm², and between about 0.5×10¹⁵ ions/cm² and about 1.5×10¹⁶ ions/cm². If the dose is smaller than about 0.5×10¹⁵ ions/cm², the concentration of rare earth metal atoms in rare earth metal oxide layers 134 can be too small and rare earth metal oxide layers 134 cannot protect isolation layers 132 from etching during S/D region formation. If the dose is greater than about 1.5×10¹⁶ ions/cm², the cost to form rare earth metal oxide layers 134 can be too high. The tilt angle for the ion beam can be between about 7° and about 30°. The twist angle for the ion beam can be flexible. In some embodiments, a post-implantation anneal can be performed. The post-implantation anneal temperature can be between about 600° C. and about 1000° C. The duration of the post-implantation anneal can be between about 1 second and about 300 seconds. The post-implantation anneal can be performed in an oxygen (O₂) and nitrogen (N₂) atmosphere.

Referring to FIG. 8B, the concentration of the rare earth metal atoms implanted in isolation layers 132 and liners 130 can increase with depth first and then decrease. The most concentrated point with respect to depth can be shallower with lower ion beam energy and can be deeper with higher ion beam energy. The concentration of the rare earth metal atoms implanted at the most concentrated point is greater with lower ion beam energy and smaller with higher ion beam energy. The entire depth of implantation can be smaller with lower ion beam energy and greater with higher ion beam energy. In some embodiments, the concentration of the rare earth metal atoms implanted in isolation layers 132 and liners 130 can decrease with depth from the top surface of isolation layers 132 and liners 130. Referring to FIG. 8C, the concentration of the rare earth metal atoms implanted in top Si layers 304 can change with respect to depth and ion beam energy in a manner similar to the concentration change described with reference to FIG. 8B. The concentration of the rare earth metal atoms implanted at the most concentrated point is greater in isolation layers 132 and liners 130 and smaller in top Si layers 304.

Referring to FIGS. 8D and 8E, the top portions of isolation layers 132 and liners 130 are removed to form isolation layer openings 802, and rare earth metal oxide layers 134 are formed in isolation layer openings 802. Referring to FIG. 8D, the top portions of isolation layers 132 and liners 130 can be removed by dry etching (e.g., reactive ion etching process) and isolation layer openings 802 can be formed. Referring to FIG. 8E, rare earth metal oxide layers 134 can be deposited in isolation layer openings 802. In some embodiments, rare earth metal oxide layers 134 can be deposited by an ALD process. By way of example and not limitation, the deposited rare earth metal oxide layers 134 can include terbium oxide (Tb₂O₃). A precursor gas terbium tris(isopropylcyclopentadienyl) (Tb(iPrCp)₃) can be used in the ALD process. The precursor gas Tb(iPrCp)₃ can be supplied between about 3 seconds and about 5 seconds, between about 2 seconds and about 7 seconds, and between about 1 second and about 10 seconds. If the duration of the precursor gas Tb(iPrCp)₃ is smaller than about 1 second, the concentration of the rare earth metal atoms in rare earth metal oxide layers 134 can be too small and rare earth metal oxide layers 134 cannot protect isolation layers 132 from etching during S/D region formation. If the duration of the precursor gas Tb(iPrCp)₃ is greater than about 10 seconds, the cost to form rare earth metal oxide layers 134 can be too high.

A first argon (Ar) gas can be supplied following the precursor gas Tb(iPrCp)₃ and the duration of the first Ar gas can be between about 10 seconds and about 30 seconds. Ozone (O₃) gas can be supplied following the first Ar gas and the duration of the O₃ gas can be between about 1 second and about 5 seconds. A second Ar gas can be supplied following the O₃ gas and the duration of the second Ar gas can be between about 10 seconds and about 30 seconds. To form rare earth metal oxide layers 134 including other rare earth metals than Tb, other suitable precursor gases can be used. Other suitable precursor gases can include a rare earth metal, such as Hf, La, In, Rh, Pd, In, Ce, Pr, Nd, Pm, Sm, Eu, Gd, Dy, Ho, Er, Tm, Yb, Lu, and combinations thereof. The growth temperature of the deposited rare earth metal oxide layers 134 can be between about 100° C. and about 400° C. In some embodiments, a CMP process can follow the deposition of rare earth metal oxide layers 134 in isolation layer openings 802, such that the top portions of cladding layers 502 are removed, and rare earth metal oxide layers 134, cladding layers 502, and top Si layers 304 are substantially coplanar with each other. In some embodiments, a post-deposition anneal can be performed. The post-deposition anneal temperature can be between about 600° C. and about 1000° C. The duration of the post-deposition anneal can be between about 1 second and about 1800 seconds. The post-deposition anneal can be performed in an O₂ and N₂ atmosphere.

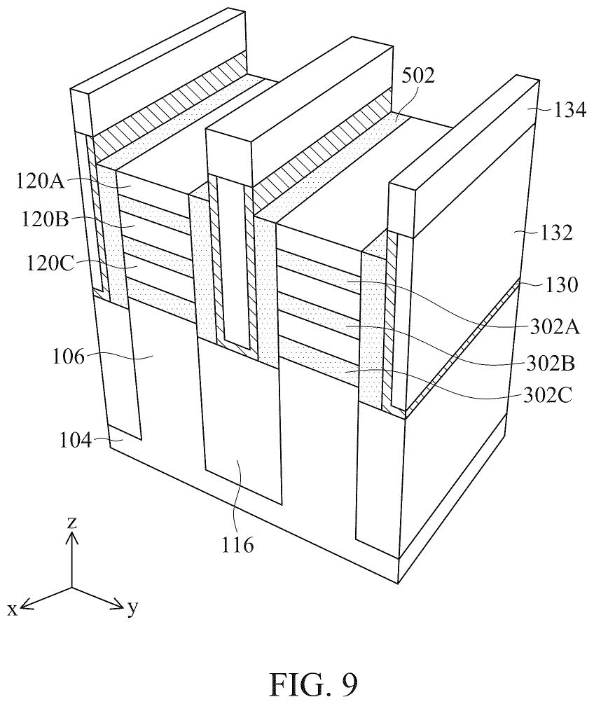

Referring to FIG. 2A, in operation 214, top Si layers, top SiGe layers, and portions of the cladding layers are removed to expose the second-type nanostructured layers. For example, as shown in FIG. 9, top Si layers 304, top SiGe layers 302D, and portions of cladding layers 502 along sidewalls of top Si layers 304 and top SiGe layers 302D are removed and second-type nanostructured layers 120A are exposed. Top Si layers 304, top SiGe layers 302D, and portions of cladding layers 502 can be removed and recessed by an etching process (e.g., reactive ion etching and other dry etching process using a chlorine (Cl) and fluorine (F) based etchant).

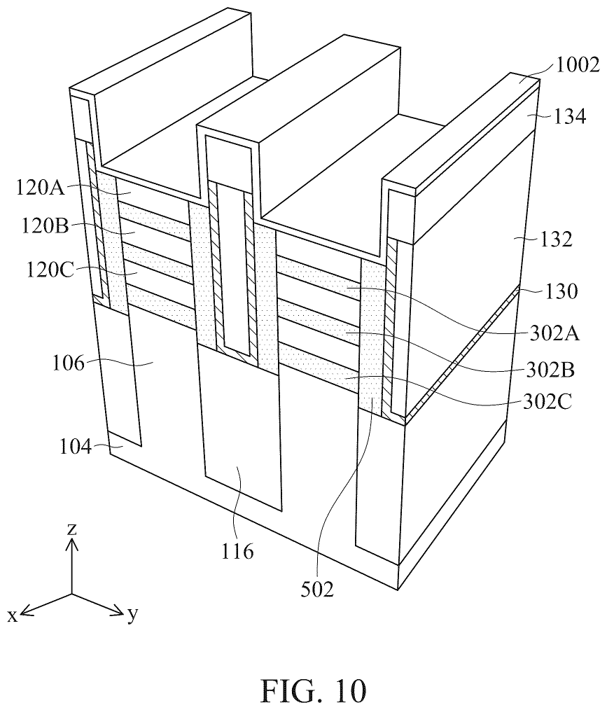

Referring to FIG. 2A, in operation 216, an IO layer is deposited on the exposed second-type nanostructured layers and the rare earth metal oxide layer. For example, as shown in FIG. 10, an IO layer 1002 is deposited on rare earth metal oxide layers 134, second-type nanostructured layers 120A, and cladding layers 502. IO layer 1002 can be an insulating material and can be deposited using CVD, PVD, and PECVD.

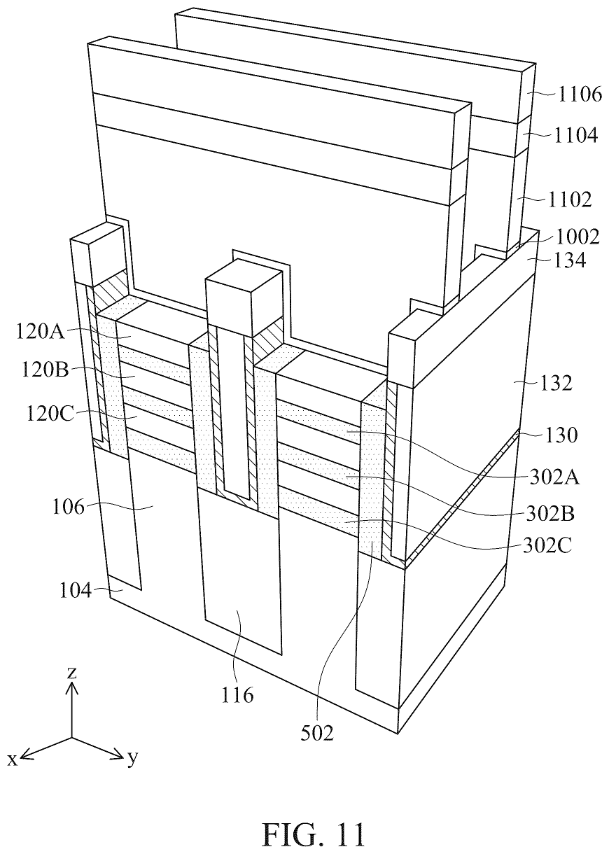

Referring to FIG. 2A, in operation 218, polysilicon structures are formed over the IO layer. For example, as shown in FIG. 11, polysilicon structures 1102 are formed over fin structures 106 and IO layers 1002. The formation of polysilicon structures 1102 can include blanket depositing a layer of polysilicon material over fin structures 106 and IO layer 1002 using CVD, PVD, ALD, and other suitable deposition processes, and removing portions of the layer of polysilicon material using a photolithographic patterning process and an etching process. Portions of IO layers 1002 can also be removed by the etching process. In some embodiments, Si₃N₄ hard mask layers 1104 and SiO₂ hard mask layers 1106 can be formed on polysilicon structures 1102. Si₃N₄ hard mask layers 1104 and SiO₂ hard mask layers 1106 can be deposited using CVD, PVD, and PECVD and patterned using the photolithographic patterning process and the etching process.

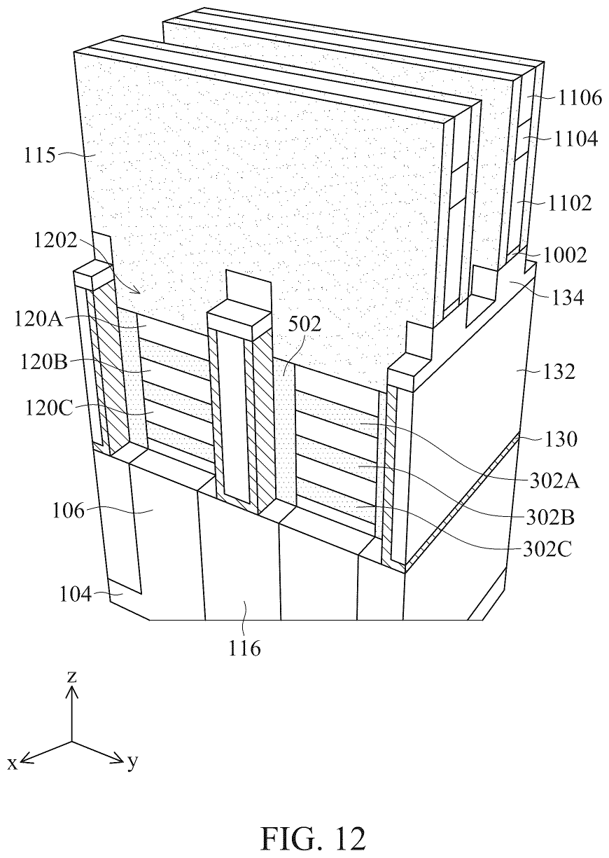

Referring to FIG. 2A, in operation 220, spacers are formed on the polysilicon structure and portions of the fin structures adjacent to the polysilicon structure are removed to form S/D openings. For example, as shown in FIG. 12, spacers 115 are formed on polysilicon structures 1102. The formation of spacers 115 can include blanket depositing a layer of an insulating material (e.g., an oxide and a nitride material) over fin structures 106 and polysilicon structures 1102 by a CVD, a PVD, and an ALD process followed by an etching process (e.g., reactive ion etching and other dry etching process using a chlorine (Cl) and fluorine (F) based etchant).

Also as shown in FIG. 12, portions of fin structures 106 adjacent to polysilicon structures 1102 are removed to form S/D openings 1202. S/D openings 1202 can be formed by a dry etching process (e.g., reactive ion etching process). The dry etching process can use a gas mixture having CₓF_{y}, N₂, and Ar. S/D openings 1202 can be formed by a wet etching process, additionally and/or alternatively. The wet etching process can include a diluted solution of hydrofluoric acid (HF) with a buffer, such as ammonium fluoride (NH₄F), diluted HF (HF/H₂O), phosphoric acid (H₃PO₄), sulfuric acid with deionized water (H₂SO₄/H₂O), and a combination thereof. The etching process can be a selective etching and a timed etching. Rare earth metal oxide layers 134 can protect isolation layers 132 and liners 130 from the etching process during the formation of S/D openings 1202. Protected isolation layers 132 and liners 130 can function as barriers between adjacent S/D regions during the epitaxial growth of the S/D regions. Protected isolation layers 132 and liners 130 can prevent the S/D regions from merging together. Unmerged S/D regions can reduce circuit complexity and improve device performance and reliability.

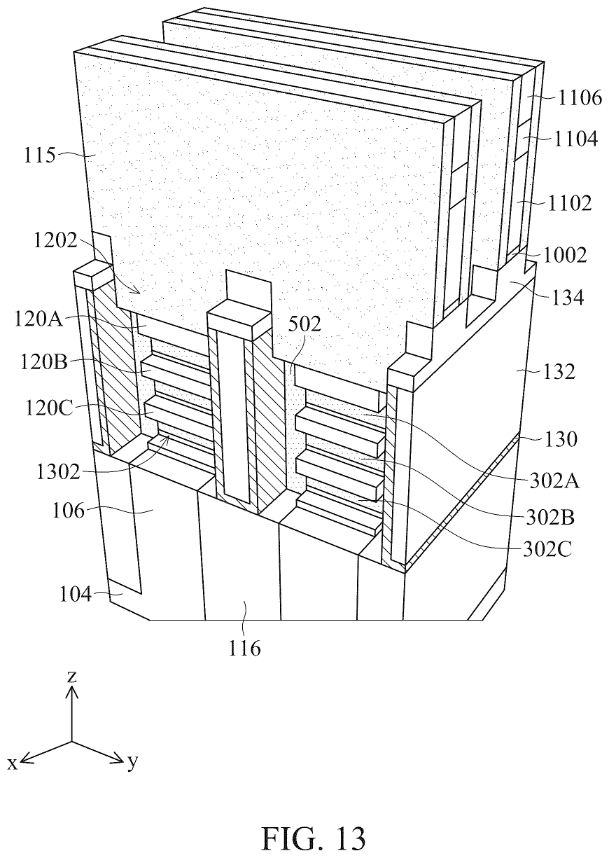

Referring to FIG. 2B, in operation 222, ends of the first-type nanostructured layers and the cladding layers are etched. For example, as shown in FIG. 13, the ends of first-type nanostructured layers 302A-302C and cladding layers 502 are etched to form inner spacer openings 1302. The ends of first-type nanostructured layers 302A-302C and cladding layers 502 can be etched by a dry etch. The dry etch can be a non-plasma chemical etching using fluorine (F₂) and hydrogen fluoride (HF).

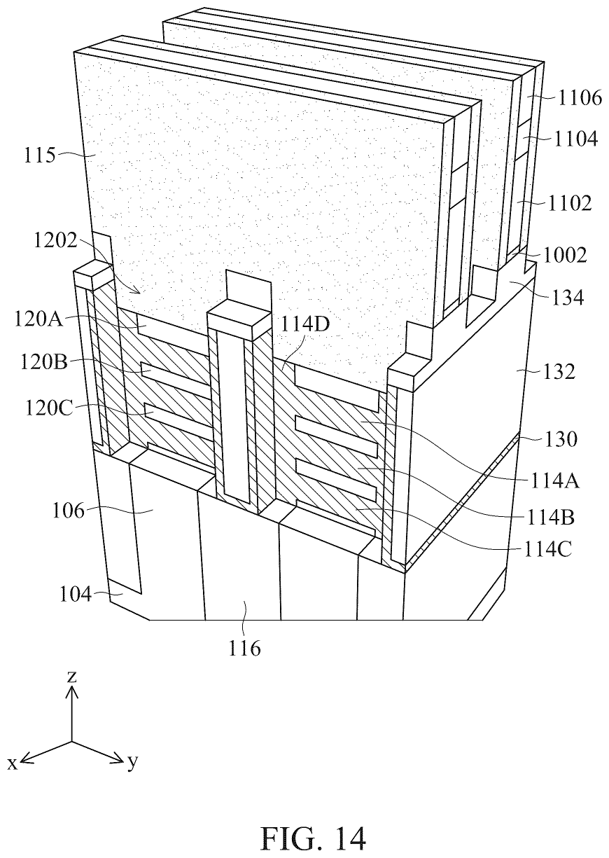

Referring to FIG. 2B, in operation 224, inner spacers are formed at the ends of the first-type nanostructured layers and the cladding layers. For example, as shown in FIG. 14, inner spacers 114A-114D are formed at the ends and sides of first-type nanostructured layers 302A-302C and cladding layers 502. The formation of inner spacers 114A-114D can include filling inner spacer openings 1302 with a dielectric material using CVD and ALD. The formation of inner spacers 114A-114D can include blanket depositing the dielectric material in and around inner spacer openings 1302 and etching the excess dielectric material outside inner spacer openings 1302.

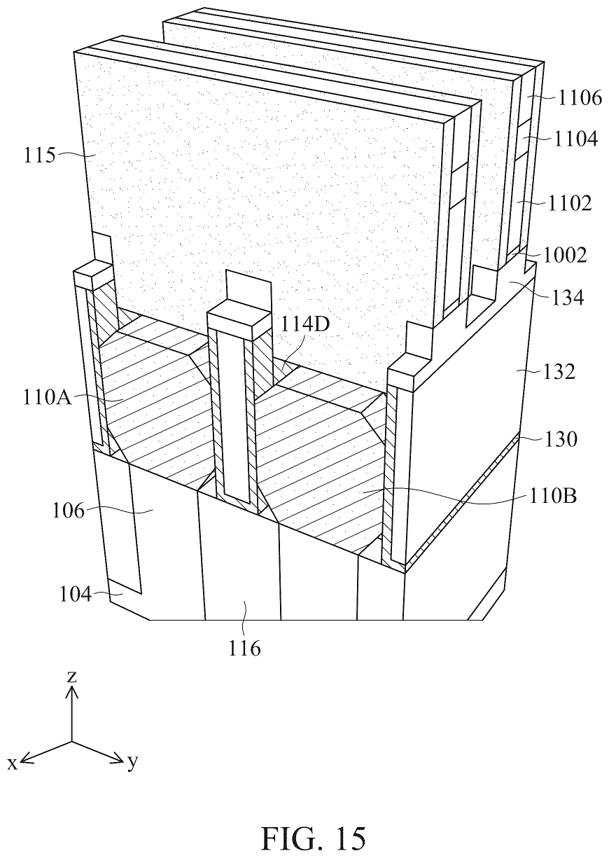

Referring to FIG. 2B, in operation 226, S/D regions are formed in the removed portions of the fin structures. For example, as shown in FIG. 15, S/D regions 110A and 110B are formed in S/D openings 1202. By way of example and not limitation, S/D regions 110A and 110B can be epitaxially grown using source gases, such as silane (SiH₄), silicon tetrachloride (SiCl₄), trichlorosilane (TCS), and dichlorosilane (SiH₂Cl₂ and DSC). Hydrogen (H₂) can be used as a reactant gas to reduce the aforementioned source gases. For example, H₂ can combine with Cl to form hydrogen chloride (HCl), leaving Si to epitaxially grow in S/D regions 110A and 110B. The growth temperature during the epitaxial growth can range from about 700° C. to about 1250° C. depending on the gases used. According to some embodiments, S/D regions 110A and 110B can have the same crystallographic orientation as substrate 104 and fin structures 106 since substrate 104 and fin structures 106 can act as a seed layer for S/D regions 110A and 110B. In some embodiments, a top surface of S/D regions 110A and 110B can be parallel to the (100) crystal plane. S/D regions 110A and 110B can be in-situ doped during their epitaxial growth process using p-type dopants, such as B, In, and Ga, or n-type dopants, such as P and As. For p-type in-situ doping, p-type doping precursors, such as diborane (B₂H₆), boron trifluoride (BF₃), and other p-type doping precursors can be used. For n-type in-situ doping, n-type doping precursors, such as phosphine (PH₃), arsine (AsH₃), and other n-type doping precursor can be used. During the formation of S/D regions 110A and 110B, if the height of isolation layers 132 and liners 130 is below a predetermined threshold, S/D regions 110A and 110B can merge together over isolation layers 132 and liners 130. Merged S/D regions 110A and 110B can increase circuit complexity. Rare earth metal oxide layers 134 can protect isolation layers 132 and liners 130 from the etching process during the formation of S/D openings 1202. The height of protected isolation layers 132 and liners 130 can be greater than the predetermined threshold and prevent S/D regions 110A and 110B from merging together over isolation layers 132 and liners 130.

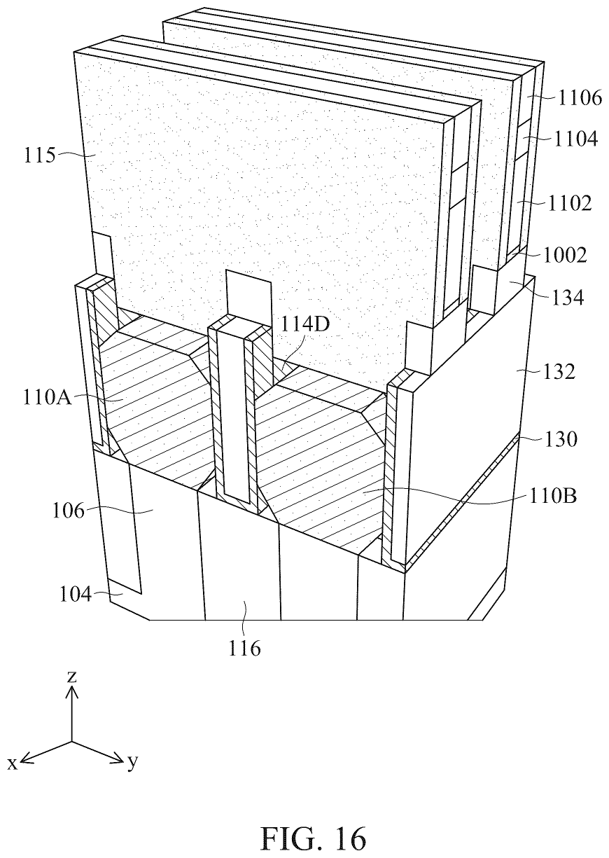

Referring to FIG. 2B, in operation 228, the rare earth metal oxide layers adjacent to the spacers are removed. For example, as shown in FIG. 16, rare earth metal oxide layers 134 adjacent to spacers 115 are removed. Rare earth metal oxide layers 134 adjacent to spacers 115 can be removed by an etching process (e.g., reactive ion etching and other plasma-enhanced dry etching process using a chlorine (Cl) and fluorine (F) based etchant). Rare earth metal oxide layers 134 below spacers 115, IO layers 1002, and polysilicon structures 1102 remain.

Referring to FIG. 2B, in operation 230, ESLs and ILD layers are deposited on the spacers and on the S/D regions. For example, as shown in FIG. 17A, ESLs 117 and ILD layers 118 are deposited on spacers 115 and S/D regions 110A and 110B. ESLs 117 and ILD layers 118 can be insulating materials deposited using PVD, CVD, and PECVD. In some embodiments, a CMP process can follow the deposition of ESLs 117 and ILD layers 118, such that Si₃N₄ hard mask layers 1104 and SiO₂ hard mask layers 1106 can be polished and polysilicon structures 1102 can be exposed for removal in the following operation. The following operations are described with respect to FIGS. 17B-20. FIG. 17B-20 illustrate isometric views of the device shown in FIG. 17A viewed from the line D-D for ease of description of the structures hidden in FIG. 17A.

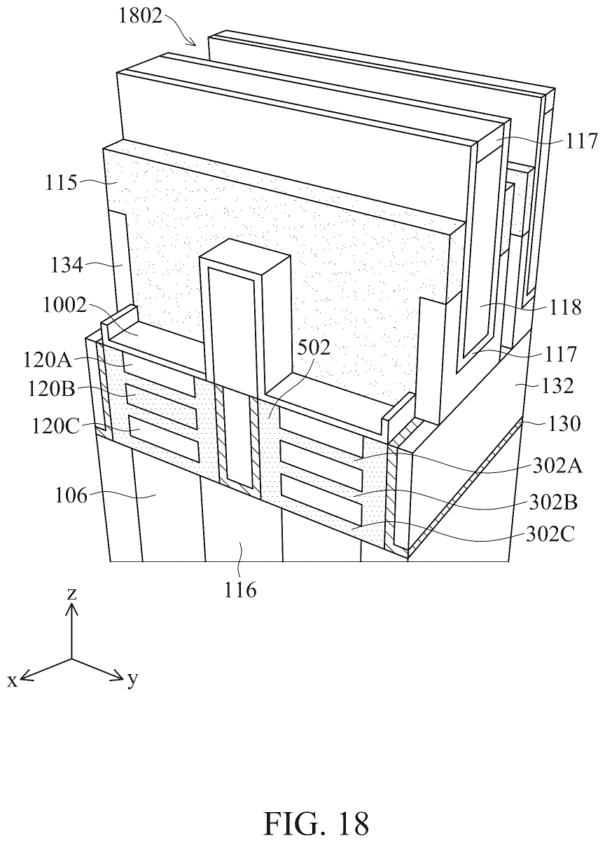

Referring to FIG. 2B, in operation 232, the polysilicon structures are removed. For example, as shown in FIG. 18, polysilicon structures 1102 are removed to form polysilicon openings 1802. Removal of polysilicon structures 1102 can be achieved using a dry etching process (e.g., reactive ion etching) and a wet etching process, each having a higher etching rate towards polysilicon structures 1102 and a lower etching rate towards spacers 115. In some embodiments, the gas etchants used in the dry etching process can include Cl, F, bromine (Br), and a combination thereof. In some embodiments, an ammonium hydroxide (NH₄OH), sodium hydroxide (NaOH), and potassium hydroxide (KOH) wet etching can be used to remove polysilicon structures 1102.

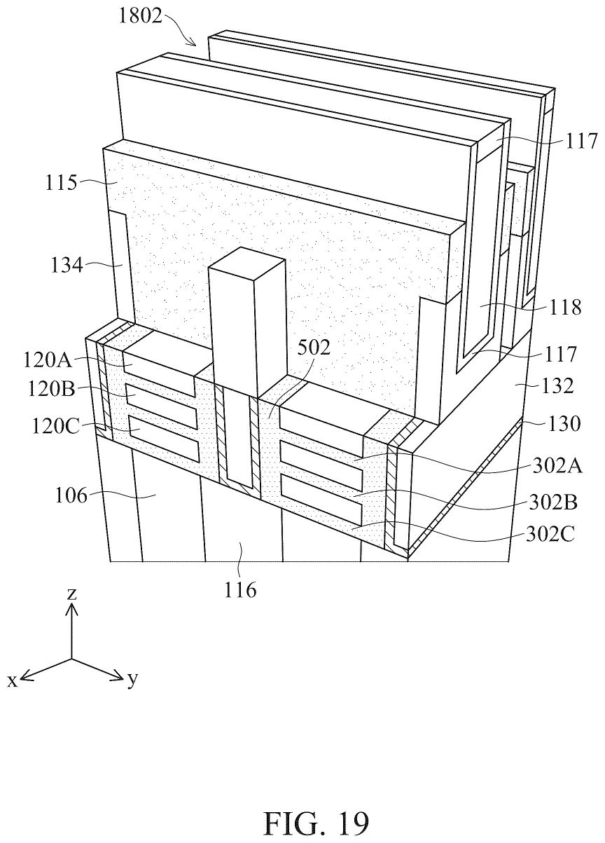

Referring to FIG. 2B, in operation 234, the IO layers are removed. For example, as shown in FIG. 19, IO layers 1002 are removed. Removal of IO layers 1002 can be achieved by an etching process (e.g., reactive ion etching and other plasma-enhanced dry etching process using a chlorine (Cl) and fluorine (F) based etchant). The dry etching process can have a higher etching rate towards IO layers 1002 and a lower etching rate towards second-type nanostructured layers 120A, cladding layers 502, and spacers 115.

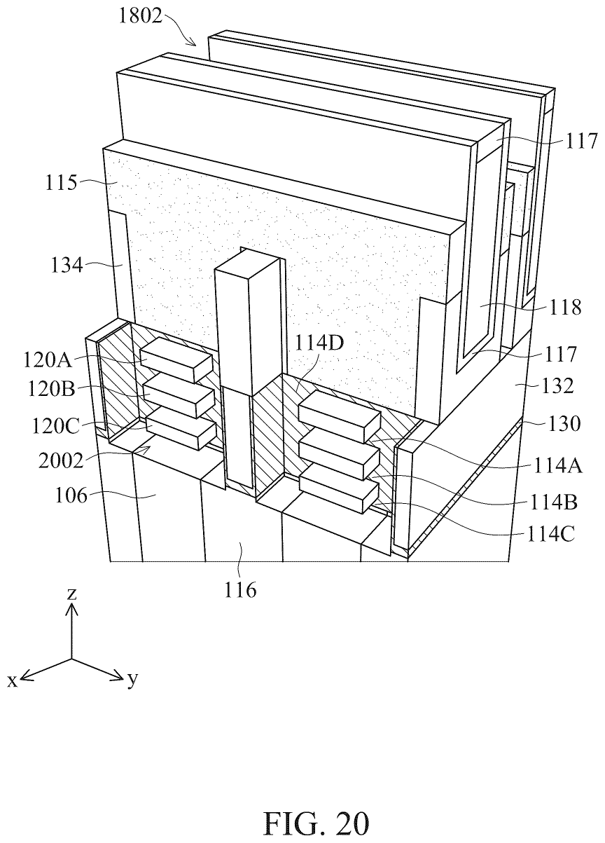

Referring to FIG. 2B, in operation 236, middle portions of the first-type nanostructured layers of the superlattice structures and the cladding layers are removed. For example, as shown in FIG. 20, the middle portions of first-type nanostructured layers 302A-302C and cladding layers 502 are removed to form first-type nanostructure openings 2002. Removal of the middle portions of first-type nanostructured layers 302A-302C and cladding layers 502 can be achieved using a dry etching process (e.g., reactive ion etching) and a wet etching process, each having a higher etching rate towards the middle portions of first-type nanostructured layers 302A-302C and cladding layers 502 and a lower etching rate towards fin structures 106 and inner spacers 114A-114D. In some embodiments, the middle portions of first-type nanostructured layers 302A-302C and cladding layers 502 can be etched in a manner similar to the polysilicon structure etching described with reference to FIG. 18. In some embodiments, the middle portions of first-type nanostructured layers 302A-302C and cladding layers 502 can be etched in a manner similar to the first-type nanostructured layer end etching described with reference to FIG. 13.

Referring to FIG. 2B, in operation 238, after the polysilicon openings and the first-type nanostructure openings 2002 are formed, gates structures are formed in spaces previously occupied by the polysilicon structures and the middle portions of the first-type nanostructured layers and the cladding layers. For example, gate structures 112 can be formed in polysilicon openings 1802 and first-type nanostructure openings 2002. Gate structures 112 can include a multi-layered structure with IO layer, HK gate dielectric layer, WFM layer, and gate metal fill layer. The IO layer can be deposited using PECVD, CVD, and ALD. The HK gate dielectric layer can be deposited using PECVD, CVD, PVD, and ALD. The WFM layer can be deposited by PECVD, CVD, PVD, ALD, metal organic chemical vapor deposition (MOCVD), sputtering, other suitable deposition methods, and a combination thereof. The gate metal fill layer can be formed by PECVD, CVD, PVD, ALD, MOCVD, sputtering, other suitable deposition methods, and a combination thereof.

The present disclosure provides example FET devices (e.g., FET 100, GAA FETs, finFETs, and planar FETs) with a rare earth metal oxide layer (e.g., rare earth metal oxide layer 134) in a semiconductor device and/or in an integrated circuit (IC) and an example method (e.g., method 200) for fabricating the same. The rare earth metal oxide layer can be formed on the top portion of the isolation layer (e.g., isolation layer 132) to protect the top portion of the isolation layer from etching. There can be two methods for forming the rare earth metal oxide layer on the top portion of the isolation layer. The first method can be rare earth metal implantation on the top portion of both the isolation layer and the fin structures (e.g., fin structures 106). There can be a post-implantation anneal. The rare earth metal can react with the isolation layer to form the rare earth metal oxide layer. The top portion of the implanted fin structures can be removed, leaving the isolation layer with the rare earth metal oxide layer on the top portion of the isolation layer. The second method can be rare earth metal oxide deposition. The top portion of the isolation layer can be removed to form an isolation layer opening (e.g., isolation layer opening 802). The rare earth metal oxide layer can be deposited in the isolation layer opening and on the fin structures. The deposition can be atomic layer deposition (ALD). There can be a post-deposition anneal. The excess rare earth metal oxide layer on the isolation layer and on the fin structures can be polished using chemical-mechanical planarization (CMP). When forming the S/D regions (e.g., S/D regions 110A and 110B), portions of the fin structures adjacent to the gate structure (e.g., gate structure 112) can be removed by etching. The S/D regions can be epitaxially grown in the removed portions (e.g., S/D openings 1202) of the fin structures. During the etching of the portions of the fin structures, the rare earth metal oxide layer can protect the top portion of the isolation layer from being removed. If too much of the top portion of the isolation layer is removed, the epitaxially-grown S/D regions can merge together over the isolation layer. The merged S/D regions can increase the complexity of the circuit design and reduce device performance and reliability. Protected isolation layer can prevent the S/D regions from merging together over the isolation layer. Therefore, the rare earth metal oxide layer can reduce circuit complexity and improve device performance and reliability.

In some embodiments, a method includes forming fin structures on a substrate and forming superlattice structures on the fin structures, where each of the superlattice structures includes a first-type nanostructured layer and a second-type nanostructured layer. The method further includes forming an isolation layer between the superlattice structures, implanting a rare earth metal into a top portion of the isolation layer to form a rare earth metal oxide layer, and forming a polysilicon structure over the superlattice structures. The method further includes etching portions of the superlattice structures adjacent to the polysilicon structure to form a source/drain (S/D) opening and forming an S/D region in the S/D opening.

In some embodiments, a method includes forming fin structures on a substrate and forming superlattice structures on the fin structures, where each of the superlattice structures includes a first-type nanostructured layer and a second-type nanostructured layer. The method further includes forming an isolation layer between the superlattice structures, removing a top portion of the isolation layer to form an opening, and forming a rare earth metal oxide layer in the opening. The method further includes etching a portion of the superlattice structures to form a source/drain (S/D) opening and forming an S/D region in the S/D opening.

In some embodiments, a semiconductor device includes superlattice structures disposed on a substrate, an isolation layer interposed between the superlattice structures, and a gate structure disposed over the superlattice structures. The semiconductor device further includes a source/drain (S/D) region disposed on a portion of the superlattice structures and adjacent to the gate structure and a rare earth metal oxide layer interposed between the isolation layer and the gate structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a first substrate portion and a second substrate portion;
a first nanostructured channel region disposed on the first substrate portion;
a second nanostructured channel region disposed on the second substrate portion;
an isolation layer disposed between the first and second nanostructured channel regions;
a metal oxide layer disposed on the isolation layer; and
a gate structure disposed surrounding the metal oxide layer and the first and second nanostructured channel regions.

2. The semiconductor device of claim 1, further comprising a dielectric layer surrounding the isolation layer.

3. The semiconductor device of claim 1, wherein the metal oxide layer comprises an oxide of a rare earth metal.

4. The semiconductor device of claim 1, further comprising an etch stop layer disposed on a portion of the isolation layer that is uncovered by the metal oxide layer.

5. The semiconductor device of claim 1, wherein the gate structure comprises a gate dielectric layer, and
wherein the gate dielectric layer is in contact with the metal oxide layer.

6. The semiconductor device of claim 1, wherein the gate structure comprises a dielectric layer and a metal layer,
wherein the dielectric layer is in contact with a first portion of the metal oxide layer, and
wherein the metal layer is in contact with a second portion of the metal oxide layer.

7. The semiconductor device of claim 1, further comprising a source/drain region with first and second vertical surfaces, wherein the first vertical surface faces the first nanostructured channel region and the second vertical surface faces the isolation layer.

8. The semiconductor device of claim 1, further comprising inner spacers surrounding portions of the first and second nanostructured channel regions that are uncovered by the gate structure.

9. The semiconductor device of claim 1, wherein the metal oxide layer comprises a composition of MₓSi_{y}O_{z}, and
wherein M is a rare earth metal.

10. The semiconductor device of claim 1, wherein a concentration of a metal of the metal oxide layer decreases from a top surface of the metal oxide layer to a bottom surface of the metal oxide layer.

11. A semiconductor device, comprising:
a substrate;
first and second source/drain regions disposed on the substrate;
a gate structure disposed on the substrate;
an isolation structure comprising first and second isolation portions, wherein the first isolation portion is disposed between the first and second source/drain regions, and wherein the second isolation portion is disposed in the gate structure; and
a metal oxide layer disposed on the second isolation portion.

12. The semiconductor device of claim 11, further comprising a dielectric layer disposed on the first isolation portion and the first and second source/drain regions.

13. The semiconductor device of claim 11, wherein a dielectric layer of the gate structure is in contact with sidewalls of the second isolation portion and the metal oxide layer.

14. The semiconductor device of claim 11, wherein a metal layer of the gate structure is in contact with sidewalls and a top surface of the metal oxide layer.

15. The semiconductor device of claim 11, further comprising a nanostructured semiconductor layer disposed adjacent to the isolation structure and surrounded by the gate structure.

16. The semiconductor device of claim 11, wherein the metal oxide layer comprises a rare earth metal.

17. A method, comprising:
forming a first nanostructured layer on a first portion of a substrate;
forming a second nanostructured layer on a second portion of the substrate;
forming an isolation structure between the first and second nanostructured layers;
converting a portion of the isolation structure into a metal oxide layer;
etching the first and second nanostructured layers to form first and second source/drain openings; and
forming first and second source/drain regions in the first and second source/drain openings, respectively.

18. The method of claim 17, wherein converting the portion of the isolation structure into the metal oxide layer comprises implanting rare earth metal atoms into the portion of the isolation structure.

19. The method of claim 17, further comprising forming a polysilicon structure on the metal oxide layer and the first and second nanostructured layers.

20. The method of claim 17, further comprising depositing a metal layer on the metal oxide layer.
